(19) United States
(12) Patent Application Publication
(10) Pub. No.: US 2004/0253547 A1
(43) Pub. Date: Dec. 16, 2004

(54) Pattern formation method

(75) Inventors: Masayuki Endo, Osaka (JP); Masaru Sasago, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/661,540

(22) Filed: Sep. 15, 2003

(30) Foreign Application Priority Data
Jun. 12, 2003 (JP) 2003-168255

(51) Int. Cl. G03F 7/00

(52) U.S. Cl. 430/322; 430/324

(57) ABSTRACT

After forming a resist film of a chemically amplified resist material, pattern exposure is carried out by selectively irradiating the resist film with exposing light while supplying, onto the resist film, a solution of perfluoropolyether that includes water and is circulated and temporarily stored in a solution storage. After the pattern exposure, the resist film is subjected to post-exposure bake and then is developed with an alkaline developer. Thus, a resist pattern made of an unexposed portion of the resist film can be formed in a good shape.

### BACKGROUND OF THE INVENTION

The present invention relates to a pattern formation method for use in fabrication process and the like for semiconductor devices.

In accordance with the increased degree of integration of semiconductor integrated circuits and downsizing of semiconductor devices, there are increasing demands for further rapid development of lithography technique. Currently, pattern formation is carried out through photolithography using exposing light of a mercury lamp, KrF excimer laser, ArF excimer laser or the like, and use of F₂ laser lasing at a shorter wavelength is being examined. However, since there remain a large number of problems in exposure systems and resist materials, photolithography using exposing light of a shorter wavelength has not been put to practical use.

In these circumstances, immersion lithography has been recently proposed for realizing further refinement of patterns by using conventional exposing light (M. Switkes and M. Rothschild, “Immersion lithography at 157 nm”, J. Vac. Sci. Technol., B19, 2353 (2001)).

In the immersion lithography, a region in an exposure system sandwiched between a projection lens and a resist film formed on a wafer is filled with a solution having a refractive index n, and therefore, the NA (numerical aperture) of the exposure system has a value n·NA. As a result, the resolution of the resist film can be improved.

Now, a conventional pattern formation method using the immersion lithography will be described with reference to FIGS. 9A through 9D.

First, a positive chemically amplified resist material having the following composition is prepared:

| | |
|---|---|
| Base polymer: poly((norbornene- | 2 g |
| 5-methylene-t-butylcarboxylate) - (maleic | |
| anhydride)) (wherein norbornene-5-methylene-t- | |
| butylcarboxylate:maleic anhydride = 50 mol %:50 mol %) | |
| Acid generator: triphenylsulfonium nonaflate | 0.06 g |
| Solvent: propylene glycol monomethyl ether acetate | 20 g |

Next, as shown in FIG. 9A, the aforementioned chemically amplified resist material is applied on a substrate 1 so as to form a resist film 2 with a thickness of 0.20 μm.

Then, as shown in FIG. 9B, while supplying perfluoropolyether 3 onto the resist film 2, pattern exposure is carried out by irradiating the resist film 2 with exposing light 4 of F₂ laser with NA of 0.60 through a mask 5. Although a projection lens for condensing the exposing light 4 having passed through the mask 5 on the surface of the resist film 2 is not shown in FIG. 9B, a region sandwiched between the projection lens and the resist film 2 is filled with the perfluoropolyether 3. Thus, an exposed portion 2a of the resist film 2 becomes soluble in an alkaline developer because an acid is generated from the acid generator therein while an unexposed portion 2b of the resist film 2 remains insoluble in an alkaline developer because no acid is generated from the acid generator therein.

After the pattern exposure, as shown in FIG. 9C, the resist film 2 is baked with a hot plate at a temperature of 100° C. for 60 seconds, and the resultant resist film is developed with a 2.38 wt % tetramethylammonium hydroxide developer (alkaline developer). In this manner, a resist pattern 6 made of the unexposed portion 2b of the resist film 2 can be obtained as shown in FIG. 9D.

As shown in FIG. 9D, however, the resist pattern 6 formed by the conventional pattern formation method is in a defective T-top shape.

Since the positive chemically amplified resist material is used in the conventional pattern formation method, the resist pattern 6 is in the T-top shape. When a negative chemically amplified resist material is used instead, the resultant resist pattern is in a defective shape with round shoulders.

When a resist pattern in such a defective shape is used for etching a target film, the resultant pattern is also in a defective shape, which disadvantageously lowers the productivity and the yield in the fabrication process for semiconductor devices.

### SUMMARY OF THE INVENTION

In consideration of the aforementioned conventional problem, an object of the invention is forming a resist pattern in a good shape by the immersion lithography.

In order to achieve the object, the present inventors have examined the cause of the defective shape of the conventional resist pattern formed by the immersion lithography, resulting in finding the following: Since the pattern exposure is carried out while supplying, onto the resist film, a water-repellent nonaqueous solution of, for example, perfluoropolyether, the water-repellent nonaqueous solution remains on the resist film in the development performed after the pattern exposure. This remaining nonaqueous solution inhibits the developer from permeating into the resist film. Also, it has been found that when water is present on a resist film after the pattern exposure, a developer can easily permeate into the resist film owing to the affinity of the water. The present invention was devised on the basis of these findings and is specifically practiced as follows:

The first pattern formation method of this invention includes the steps of forming a resist film; performing pattern exposure by selectively irradiating the resist film with exposing light while supplying, onto the resist film, a nonaqueous solution including water; and forming a resist pattern by developing the resist film after the pattern exposure.

In the first pattern formation method, since the nonaqueous solution includes water, the surface of the resist film attains affinity owing to the water after the pattern exposure, so that a developer can easily permeate into the resist film. Accordingly, the resist pattern can be formed in a good shape, and hence, a pattern of a target film etched by using the resist pattern can be also in a good shape.

The second pattern formation method of this invention includes the steps of forming a positive resist film of a chemically amplified resist material including an acid generator for generating an acid through irradiation with light; performing pattern exposure by selectively irradiating the resist film with exposing light while supplying, onto the resist film, a nonaqueous solution including a compound for generating water in the presence of an acid; and forming a resist pattern by developing the resist film after the pattern exposure.

In the second pattern formation method, since the resist film includes the acid generator and the nonaqueous solution includes the compound for generating water in the presence of an acid, the surface of an exposed portion of the resist film attains affinity owing to generated water after the pattern exposure, so that a developer can easily permeate into the exposed portion of the resist film. Accordingly, the resist pattern can be formed in a good shape, and hence, a pattern of a target film etched by using the resist pattern can be also in a good shape.

The third pattern formation method of this invention includes the steps of forming a positive resist film; performing pattern exposure by selectively irradiating the resist film with exposing light while supplying, onto the resist film, a nonaqueous solution including an acid generator for generating an acid through irradiation with light and a compound for generating water in the presence of an acid; and forming a resist pattern by developing the resist film after the pattern exposure.

In the third pattern formation method, since the nonaqueous solution includes the acid generator and the compound for generating water in the presence of an acid, the surface of an exposed portion of the resist film attains affinity owing to generated water after the pattern exposure, so that a developer can easily permeate into the exposed portion of the resist film. Accordingly, the resist pattern can be formed in a good shape, and hence, a pattern of a target film etched by using the resist pattern can be also in a good shape.

The fourth pattern formation method of this invention includes the steps of forming a positive resist film of a chemically amplified resist material including an acid generator for generating an acid through irradiation with light; forming, on the resist film, a water-soluble film including a compound for generating water in the presence of an acid; performing pattern exposure by selectively irradiating the resist film with exposing light while supplying a nonaqueous solution onto the water-soluble film; and forming a resist pattern by developing the resist film after the pattern exposure.

In the fourth pattern formation method, since the resist film includes the acid generator and the water-soluble film formed on the resist film includes the compound for generating water in the presence of an acid, the surfaces of the water-soluble film and an exposed portion of the resist film attain affinity owing to generated water after the pattern exposure, so that a developer can easily permeate into the exposed portion of the resist film. Accordingly, the resist pattern can be formed in a good shape, and hence, a pattern of a target film etched by using the resist pattern can be also in a good shape.

The fifth pattern formation method of this invention includes the steps of forming a positive resist film; forming, on the resist film, a water-soluble film including an acid generator for generating an acid through irradiation with light and a compound for generating water in the presence of an acid; performing pattern exposure by selectively irradiating the resist film with exposing light while supplying a nonaqueous solution onto the water-soluble film; and forming a resist pattern by developing the resist film after the pattern exposure.

In the fifth pattern formation method, since the water-soluble film formed on the resist film includes the acid generator and the compound for generating water in the presence of an acid, the surfaces of the water-soluble film and an exposed portion of the resist film attain affinity owing to generated water after the pattern exposure, so that a developer can easily permeate into the exposed portion of the resist film. Accordingly, the resist pattern can be formed in a good shape, and hence, a pattern of a target film etched by using the resist pattern can be also in a good shape.

The sixth pattern formation method of this invention includes the steps of forming a positive resist film of a chemically amplified resist material including an acid generator for generating an acid through irradiation with light and a compound for generating water in the presence of an acid; performing pattern exposure by selectively irradiating the resist film with exposing light while supplying a nonaqueous solution onto the resist film; and forming a resist pattern by developing the resist film after the pattern exposure.

In the sixth pattern formation method, since the resist film includes the acid generator and the compound for generating water in the presence of an acid, the surface of an exposed portion of the resist film attains affinity owing to generated water after the pattern exposure, so that a developer can easily permeate into the exposed portion of the resist film. Accordingly, the resist pattern can be formed in a good shape, and hence, a pattern of a target film etched by using the resist pattern can be also in a good shape.

In each of the first through sixth pattern formation methods, the nonaqueous solution can be perfluoropolyether.

In each of the first through sixth pattern formation methods, the exposing light is preferably F₂ laser.

In each of the second through sixth pattern formation methods, the nonaqueous solution preferably includes water.

Thus, the affinity of the exposed portion of the resist film can be further improved, and hence, the developer can more easily permeate into the exposed portion of the resist film.

In each of the fourth through sixth pattern formation methods, the nonaqueous solution preferably includes a compound for generating water in the presence of an acid.

Thus, the affinity of the exposed portion of the resist film can be further improved, and hence, the developer can more easily permeate into the exposed portion of the resist film.

In the second or fourth pattern formation method, the chemically amplified resist material preferably includes a compound for generating water in the presence of an acid.

Thus, the affinity of the exposed portion of the resist film can be further improved, and hence, the developer can more easily permeate into the exposed portion of the resist film.

In each of the second through sixth pattern formation methods, the acid generator can be an onium salt, a halogen-containing compound, a diazoketone compound, a diazomethane compound, a sulfone compound, a sulfonic ester compound or a sulfonimide compound.

In each of the second through sixth pattern formation methods, the compound for generating water in the presence of an acid can be a tertiary alcohol, a diol of a tertiary alcohol, a secondary alcohol or a diol of a secondary alcohol.

In the fourth or fifth pattern formation method, the water-soluble film can be a polyvinyl alcohol film or a polyvinyl pyrrolidone film.

### BRIEF DESCRIPTION OF THE DRAWINGS

FIG. 1 is a partial cross-sectional view of an exposure system commonly used in preferred embodiments of the invention;

FIGS. 2A, 2B, 2C and 2D are cross-sectional views for showing procedures in a pattern formation method according to Embodiment 1 of the invention;

FIGS. 3A, 3B, 3C and 3D are cross-sectional views for showing procedures in a pattern formation method according to Embodiment 2 of the invention;

FIGS. 4A, 4B, 4C and 4D are cross-sectional views for showing procedures in a pattern formation method according to Embodiment 3 of the invention;

FIGS. 5A, 5B, 5C and 5D are cross-sectional views for showing procedures in a pattern formation method according to Embodiment 4 of the invention;

FIGS. 6A, 6B, 6C and 6D are cross-sectional views for showing procedures in a pattern formation method according to Embodiment 5 of the invention;

FIGS. 7A, 7B, 7C and 7D are cross-sectional views for showing procedures in a pattern formation method according to Embodiment 6 of the invention;

FIGS. 8A, 8B, 8C and 8D are cross-sectional views for showing procedures in a pattern formation method according to Embodiment 7 of the invention; and

FIGS. 9A, 9B, 9C and 9D are cross-sectional views for showing procedures in a conventional pattern formation method.

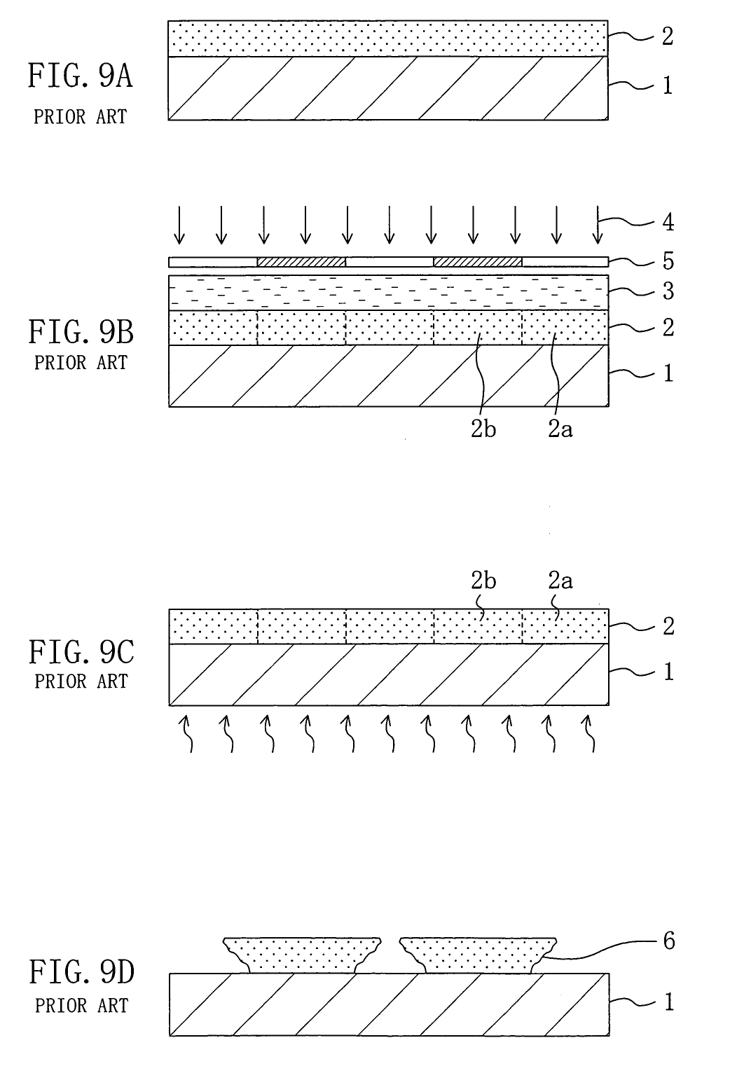

### DETAILED DESCRIPTION OF THE INVENTION

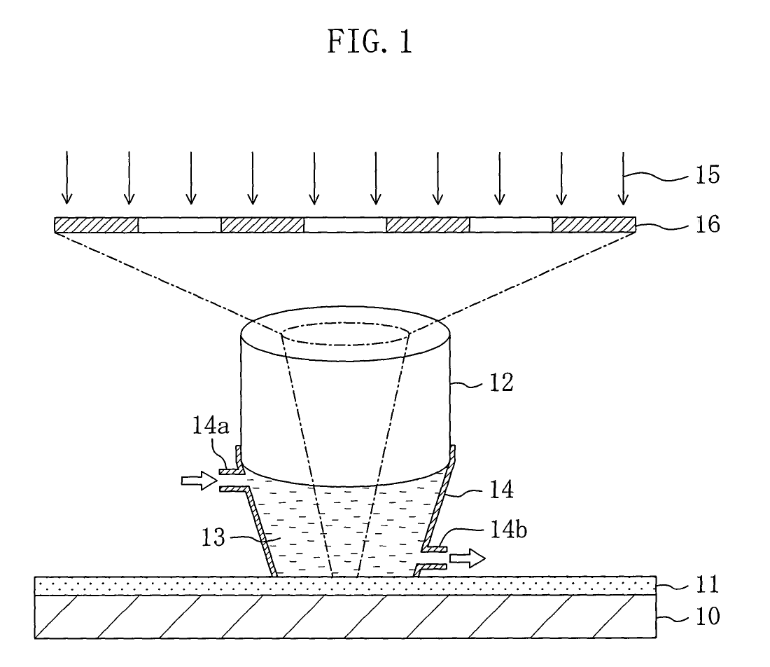

Pattern formation methods according to preferred embodiments of the invention will now be described, and first of all, an exposure system used in each embodiment will be described with reference to FIG. 1. It is noted that the exposure system used in the pattern formation method of each embodiment is not limited to one having the structure shown in FIG. 1 but any of systems capable of realizing the immersion lithography can be used.

As shown in FIG. 1, a projection lens 12 of the exposure system is provided above a resist film 11 formed on a semiconductor substrate 10, and a solution storage 14 for storing a solution 13 (with a refractive index n) is provided between the projection lens 12 and the resist film 11. The solution storage 14 is provided with an inlet 14a for allowing the solution 13 to flow into and an outlet 14b for allowing the solution 13 to flow out of the solution storage 14, and the solution 13 having flown into the solution storage 14 through the inlet 14a is temporarily stored in the solution storage 14 and then flows out through the outlet 14b. Accordingly, exposing light 15 passes through a mask 16 having a desired pattern, and is then condensed by the projection lens 12 so as to reach the surface of the resist film 11 through the solution 13. Therefore, the numerical aperture NA of the exposing light that reaches the surface of the resist film 11 through the solution 13 has a value n times as large as that attained when the exposing light reaches without passing through the solution 13.

### EMBODIMENT 1

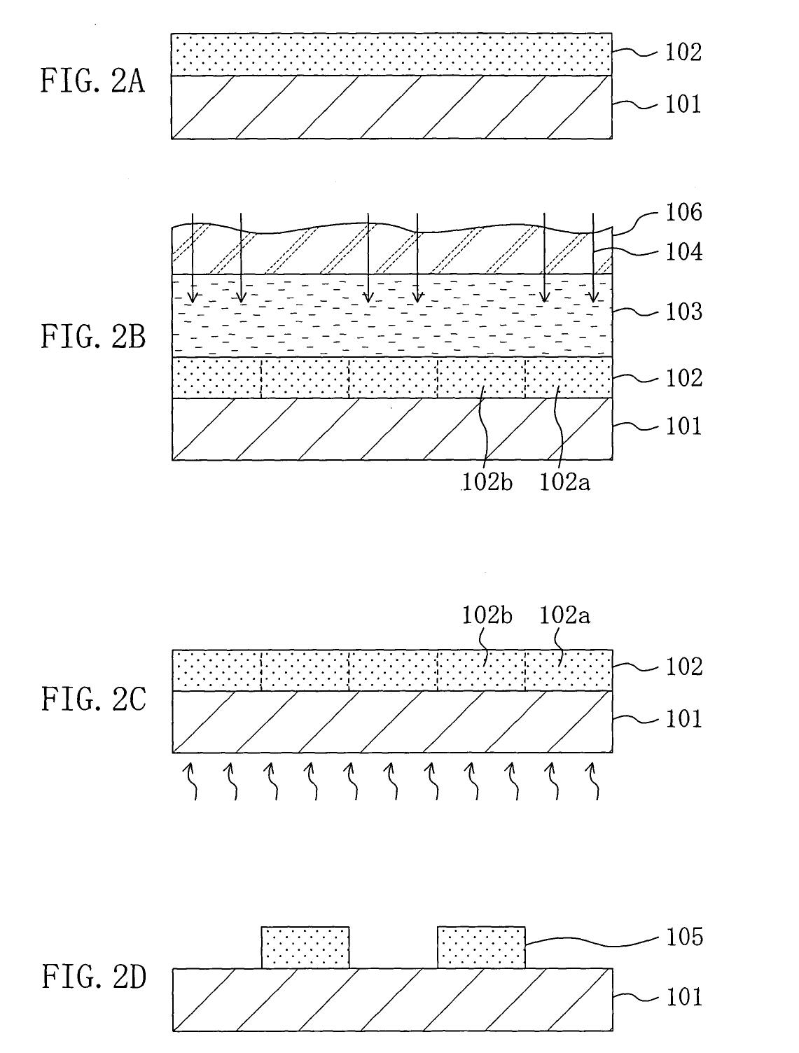

A pattern formation method according to Embodiment 1 of the invention will now be described with reference to FIGS. 2A through 2D.

First, a positive chemically amplified resist material having the following composition is prepared:

| | |
|---|---|
| Base polymer: poly((norbornene-5- | 2 g |
| methylene-t-butylcarboxylate) - (maleic | |
| anhydride)) (wherein norbornene-5-methylene-t- | |
| butylcarboxylate:maleic anhydride = 50 mol %:50 mol %) | |
| Acid generator: triphenylsulfonium nonaflate | 0.06 g |
| Solvent: propylene glycol monomethyl ether acetate | 20 g |

Next, as shown in FIG. 2A, the aforementioned chemically amplified resist material is applied on a substrate 101 so as to form a resist film 102 with a thickness of 0.20 μm.

Then, as shown in FIG. 2B, while supplying, onto the resist film 102, a nonaqueous solution 103 of perfluoropolyether (having a refractive index n of 1.37) represented by Chemical Formula 1 that includes 8 wt % of water and is circulated and temporarily stored in the solution storage 14 (shown in FIG. 1), pattern exposure is carried out by irradiating the resist film 102 with exposing light 104 of F₂ laser with NA of 0.60 through a mask not shown. In FIG. 2B, a reference numeral 106 denotes a projection lens for condensing the exposing light 104 on the resist film 102. Thus, an exposed portion 102a of the resist film 102 becomes soluble in an alkaline developer because an acid is generated from the acid generator therein while an unexposed portion 102b of the resist film 102 remains insoluble in an alkaline developer because no acid is generated from the acid generator therein.

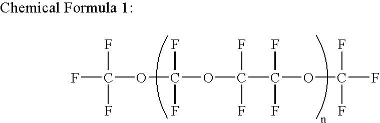

After the pattern exposure, as shown in FIG. 2C, the resist film 102 is baked with a hot plate at a temperature of 100° C. for 60 seconds, and the resultant resist film is developed with a 2.38 wt % tetramethylammonium hydroxide developer (alkaline developer). In this manner, a resist pattern 105 made of the unexposed portion 102b of the resist film 102 and having a line width of 0.06 μm can be formed in a good shape as shown in FIG. 2D.

In Embodiment 1, since the solution 103 includes water, the surface of the resist film 102 can attain affinity owing to the water after the pattern exposure, so that the developer can easily permeate into the resist film 102. As a result, the resist pattern 105 can be formed in a good shape.

### EMBODIMENT 2

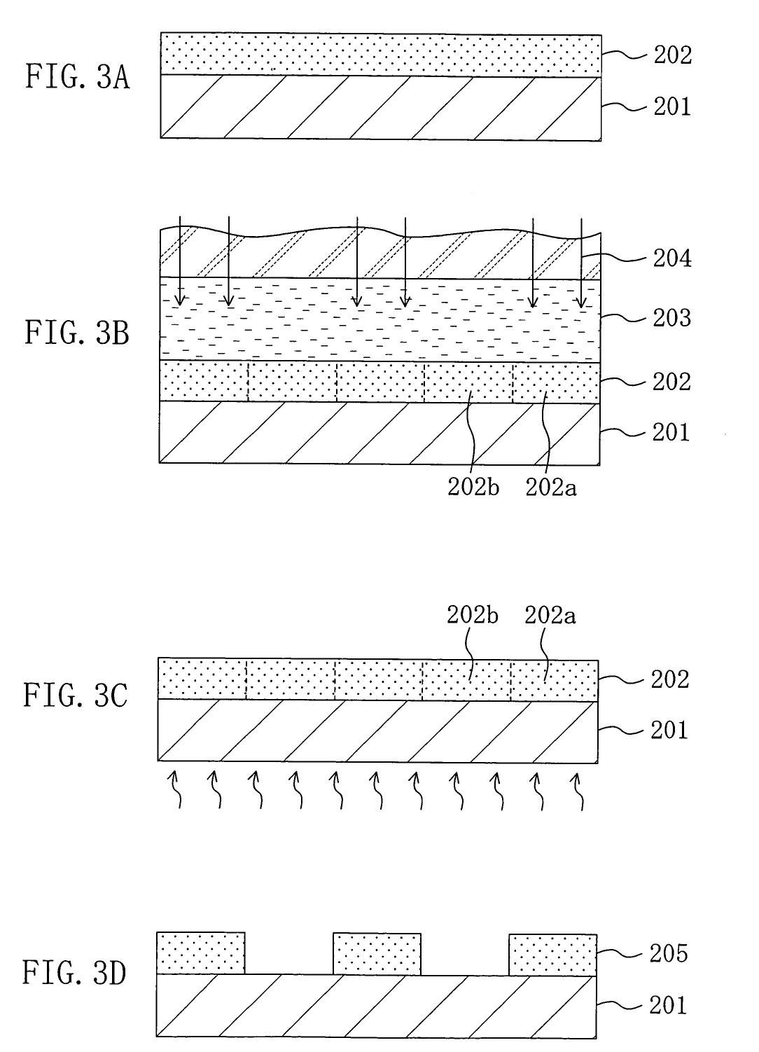

A pattern formation method according to Embodiment 2 of the invention will now be described with reference to FIGS. 3A through 3D.

First, a negative chemically amplified resist material having the following composition is prepared:

| | |
|---|---|
| Base polymer: poly((norbornene-5- | 2 g |
| methylenecarboxylic acid) - (maleic | |
| anhydride)) (wherein norbornene-5-methylenecarboxylic | |
| acid:maleic anhydride = 50 mol %:50 mol %) | |
| Crosslinking agent: 1,3,5-N-(trihydroxymethyl)melamine | 0.4 g |
| Acid generator: triphenylsulfonium nonaflate | 0.06 g |
| Solvent: propylene glycol monomethyl ether acetate | 20 g |

Next, as shown in FIG. 3A, the aforementioned chemically amplified resist material is applied on a substrate 201 so as to form a resist film 202 with a thickness of 0.20 μm.

Then, as shown in FIG. 3B, while supplying, onto the resist film 202, a nonaqueous solution 203 of perfluoropolyether (having a refractive index n of 1.37) that includes 4 wt % of water and is circulated and temporarily stored in the solution storage 14 (shown in FIG. 1), pattern exposure is carried out by irradiating the resist film 202 with exposing light 204 of F₂ laser with NA of 0.60 through a mask not shown. Thus, an exposed portion 202a of the resist film 202 becomes insoluble in an alkaline developer due to the function of the crosslinking agent because an acid is generated from the acid generator therein while an unexposed portion 202b of the resist film 202 remains soluble in an alkaline developer because no acid is generated from the acid generator therein.

After the pattern exposure, as shown in FIG. 3C, the resist film 202 is baked with a hot plate at a temperature of 110° C. for 60 seconds, and the resultant resist film is developed with a 2.38 wt % tetramethylammonium hydroxide developer (alkaline developer). In this manner, the unexposed portion 202b of the resist film 202 is dissolved in the alkaline developer, and hence, a resist pattern 205 made of the exposed portion 202a of the resist film 202 and having a line width of 0.06 μm can be formed in a good shape as shown in FIG. 3D.

In Embodiment 2, since the solution 203 includes water, the surface of the resist film 202 can attain affinity owing to the water after the pattern exposure, so that the developer can easily permeate into the resist film 202. As a result, the resist pattern 205 can be formed in a good shape.

Although the solution includes 8 wt % of water in Embodiment 1 and 4 wt % of water in Embodiment 2, the amount of water added to the solution is not particularly specified but is generally several wt %.

Also, the chemically amplified resist material is used in Embodiment 1 or 2 but a non-chemically amplified resist material may be used instead.

### EMBODIMENT 3

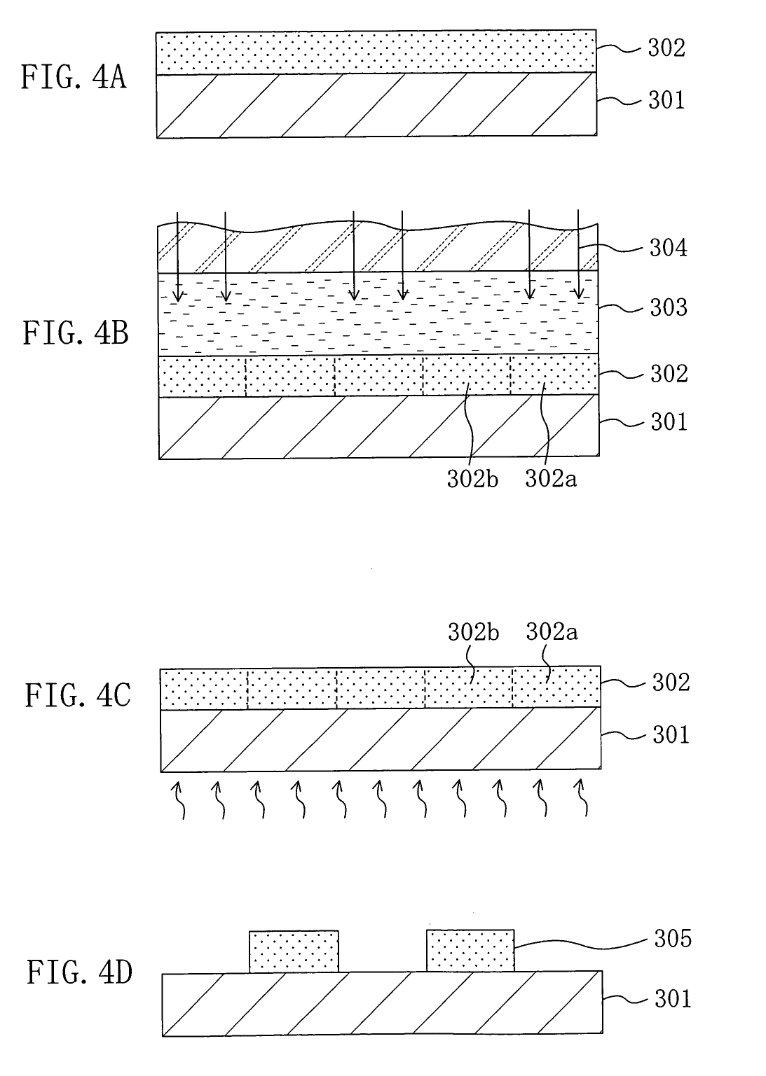

A pattern formation method according to Embodiment 3 of the invention will now be described with reference to FIGS. 4A through 4D.

First, a positive chemically amplified resist material having the following composition is prepared:

| | |
|---|---|
| Base polymer: poly((norbornene-5-methylene-t-b | 2 g |
| utylcarboxylate) - (maleic | |
| anhydride)) (wherein norbornene-5-methylene-t- | |
| butylcarboxylate:maleic anhydride = 50 mol %:50 mol %) | |
| Acid generator: triphenylsulfonium nonaflate | 0.06 g |
| Solvent: propylene glycol monomethyl ether acetate | 20 g |

Next, as shown in FIG. 4A, the aforementioned chemically amplified resist material is applied on a substrate 301 so as to form a resist film 302 with a thickness of 0.20 μm.

Then, as shown in FIG. 4B, while supplying, onto the resist film 302, a nonaqueous solution 303 of perfluoropolyether (having a refractive index n of 1.37) that includes 6 wt % of 3-methyl-1,2-butanediol, that is, a compound for generating water in the presence of an acid, and is circulated and temporarily stored in the solution storage 14 (shown in FIG. 1), pattern exposure is carried out by irradiating the resist film 302 with exposing light 304 of F₂ laser with NA of 0.60 through a mask not shown. Thus, an exposed portion 302a of the resist film 302 becomes soluble in an alkaline developer because an acid is generated from the acid generator therein while an unexposed portion 302b of the resist film 302 remains insoluble in an alkaline developer because no acid is generated from the acid generator therein.

After the pattern exposure, as shown in FIG. 4C, the resist film 302 is baked with a hot plate at a temperature of 100° C. for 60 seconds, and the resultant resist film is developed with a 2.38 wt % tetramethylammonium hydroxide developer (alkaline developer). In this manner, a resist pattern 305 made of the unexposed portion 302b of the resist film 302 and having a line width of 0.06 μm can be formed in a good shape as shown in FIG. 4D.

In Embodiment 3, since the resist film 302 includes the acid generator and the solution 303 includes the compound for generating water in the presence of an acid, the surface of the exposed portion 302a of the resist film 302 can attain affinity owing to generated water after the pattern exposure, so that the developer can easily permeate into the exposed portion 302a of the resist film 302. As a result, the resist pattern 305 can be formed in a good shape.

Although the solution 403 of Embodiment 3 includes 6 wt % of the compound for generating water in the presence of an acid, the amount of the compound added to the solution is not particularly specified but is generally several wt %.

### EMBODIMENT 4

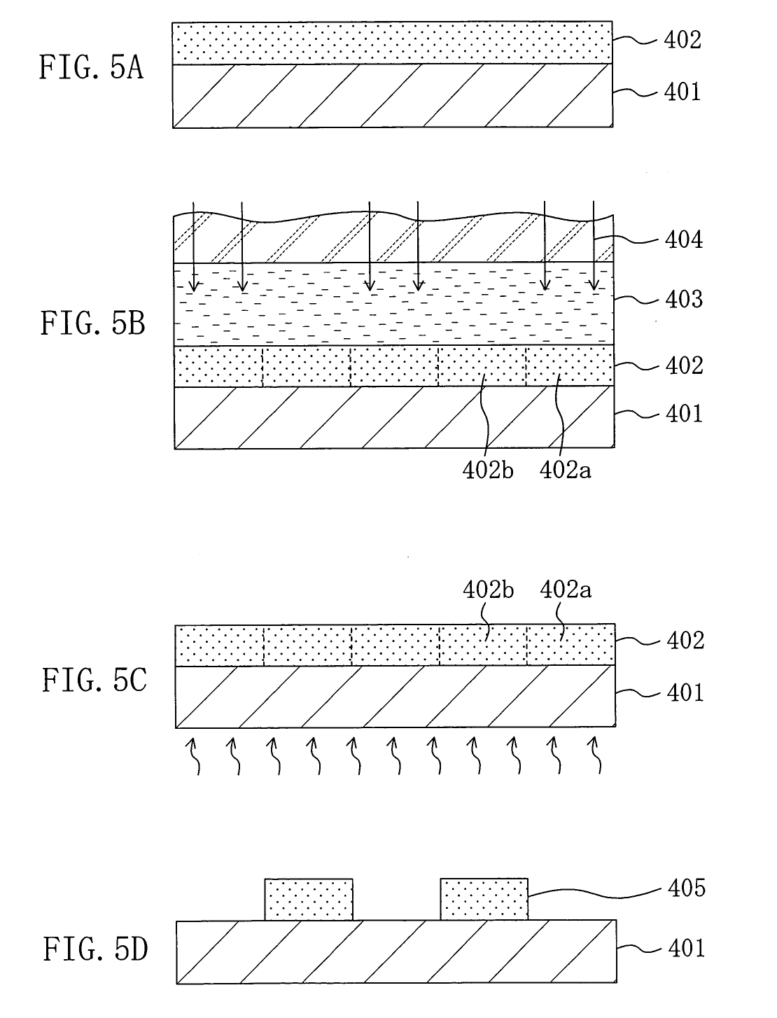

A pattern formation method according to Embodiment 4 of the invention will now be described with reference to FIGS. 5A through 5D.

First, a positive chemically amplified resist material having the following composition is prepared:

| | |
|---|---|
| Base polymer: poly((norbornene-5-methylene-t- | 2 g |
| butylcarboxylate) - (maleic | |
| anhydride)) (wherein norbornene-5-methylene-t- | |
| butylcarboxylate:maleic anhydride = 50 mol %:50 mol %) | |
| Acid generator: triphenylsulfonium nonaflate | 0.04 g |
| Solvent: propylene glycol monomethyl ether acetate | 20 g |

Next, as shown in FIG. 5A, the aforementioned chemically amplified resist material is applied on a substrate 401 so as to form a resist film 402 with a thickness of 0.20 μm.

Then, as shown in FIG. 5B, while supplying, onto the resist film 402, a nonaqueous solution 403 of perfluoropolyether (with a refractive index n of 1.37) that includes 5 wt % of 2,6-dinitrobenzyl tosylate, that is, an acid generator for generating an acid through irradiation with light, and 8 wt % of 2,4-pentanediol, that is, a compound for generating water in the presence of an acid, and is circulated and temporarily stored in the solution storage 14 (shown in FIG. 1), pattern exposure is carried out by irradiating the resist film 402 with exposing light 404 of F₂ laser with NA of 0.60 through a mask not shown. Thus, an exposed portion 402a of the resist film 402 becomes soluble in an alkaline developer because an acid is generated from the acid generator therein while an unexposed portion 402b of the resist film 402 remains insoluble in an alkaline developer because no acid is generated from the acid generator therein.

After the pattern exposure, as shown in FIG. 5C, the resist film 402 is baked with a hot plate at a temperature of 100° C. for 60 seconds, and the resultant resist film is developed with a 2.38 wt % tetramethylammonium hydroxide developer (alkaline developer). In this manner, a resist pattern 405 made of the unexposed portion 402b of the resist film 402 and having a line width of 0.06 μm can be formed in a good shape as shown in FIG. 5D.

In Embodiment 4, since the solution 403 includes the acid generator and the compound for generating water in the presence of an acid, the surface of the exposed portion 402a of the resist film 402 can attain affinity owing to generated water after the pattern exposure, so that the developer can easily permeate into the exposed portion 402a of the resist film 402. As a result, the resist pattern 405 can be formed in a good shape.

Although the solution includes 5 wt % of the acid generator and 8 wt % of the compound for generating water in the presence of an acid in Embodiment 4, the amounts of the acid generator and the compound added to the solution are not particularly specified but are generally several wt %, respectively.

Also, although the positive chemically amplified resist material is used in Embodiment 4, a positive non-chemically amplified resist material may be used instead.

### EMBODIMENT 5

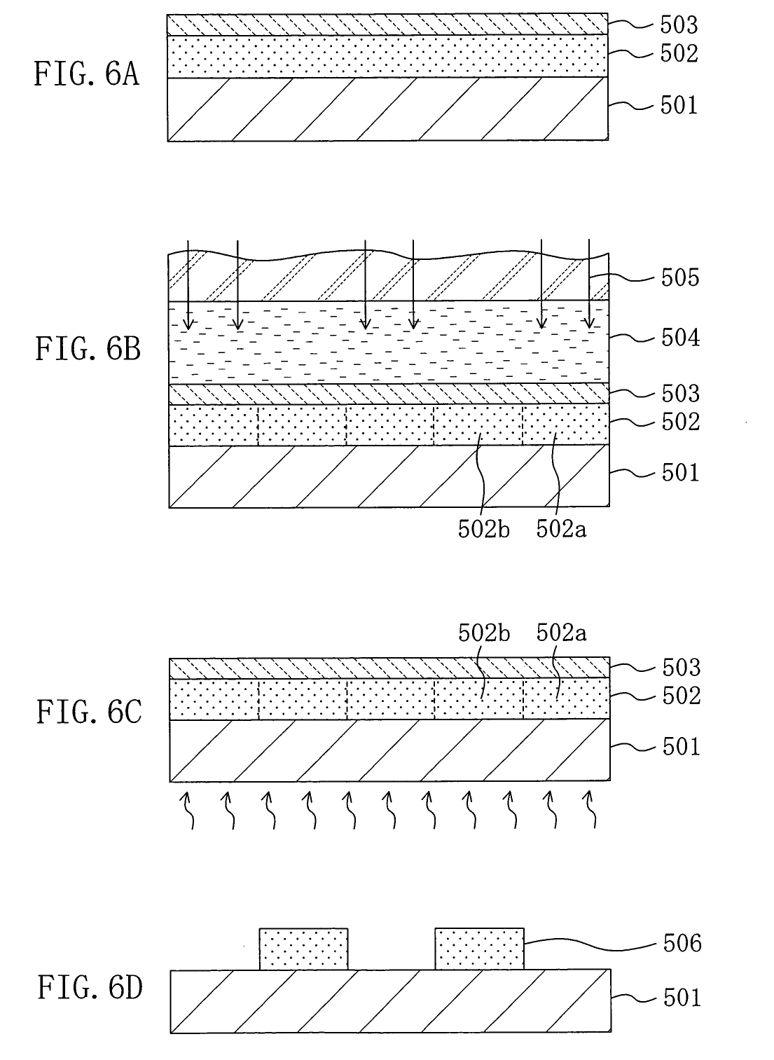

A pattern formation method according to Embodiment 5 of the invention will now be described with reference to FIGS. 6A through 6D.

First, a positive chemically amplified resist material having the following composition is prepared:

| | |
|---|---|
| Base polymer: poly((norbornene-5-methylene-t- | 2 g |
| butylcarboxylate) - (maleic | |
| anhydride)) (wherein norbornene-5-methylene-t- | |
| butylcarboxylate:maleic anhydride = 50 mol %: | |
| 50 mol %) | |
| Acid generator: triphenylsulfonium nonaflate | 0.06 g |
| Solvent: propylene glycol monomethyl ether acetate | 20 g |

Next, as shown in FIG. 6A, the aforementioned chemically amplified resist material is applied on a substrate 501 so as to form a resist film 502 with a thickness of 0.20 μm. Thereafter, a water-soluble film 503 of a polyvinyl alcohol film including 7 wt % of 2-methyl-2-butanol, that is, a compound for generating water in the presence of an acid, is formed on the resist film 502.

Then, as shown in FIG. 6B, while supplying, onto the water-soluble film 503, a solution 504 of perfluoropolyether that is circulated and temporarily stored in the solution storage 14 (shown in FIG. 1), pattern exposure is carried out by irradiating the water-soluble film 503 and the resist film 502 with exposing light 505 of F₂ laser with NA of 0.60 through a mask not shown. Thus, an exposed portion 502a of the resist film 502 becomes soluble in an alkaline developer and water is generated from the water-soluble film 503 in the exposed portion 502a because an acid is generated from the acid generator therein. On the other hand, an unexposed portion 502b of the resist film 502 remains insoluble in an alkaline developer and no water is generated from the water-soluble film 503 in the unexposed portion 502b because no acid is generated from the acid generator therein.

After the pattern exposure, as shown in FIG. 6C, the resist film 502 is baked with a hot plate at a temperature of 100° C. for 60 seconds, and the resultant resist film is developed with a 2.38 wt % tetramethylammonium hydroxide developer (alkaline developer). In this manner, the water-soluble film 503 and the exposed portion 502a of the resist film 502 are dissolved in the alkaline developer, and hence, a resist pattern 505 made of the unexposed portion 502b of the resist film 502 and having a line width of 0.06 μm can be formed in a good shape as shown in FIG. 6D.

In Embodiment 5, since the resist film 502 includes the acid generator and the water-soluble film 503 includes the compound for generating water in the presence of an acid, the surface of the exposed portion 502a of the resist film 502 can attain affinity owing to generated water after the pattern exposure, so that the developer can easily permeate into the exposed portion 502a of the resist film 502. As a result, the resist pattern 505 can be formed in a good shape.

Although the water-soluble film 503 includes 7 wt % of the compound for generating water in the presence of an acid in Embodiment 5, the amount of the compound included in the water-soluble film is not particularly specified but is generally several wt %.

### EMBODIMENT 6

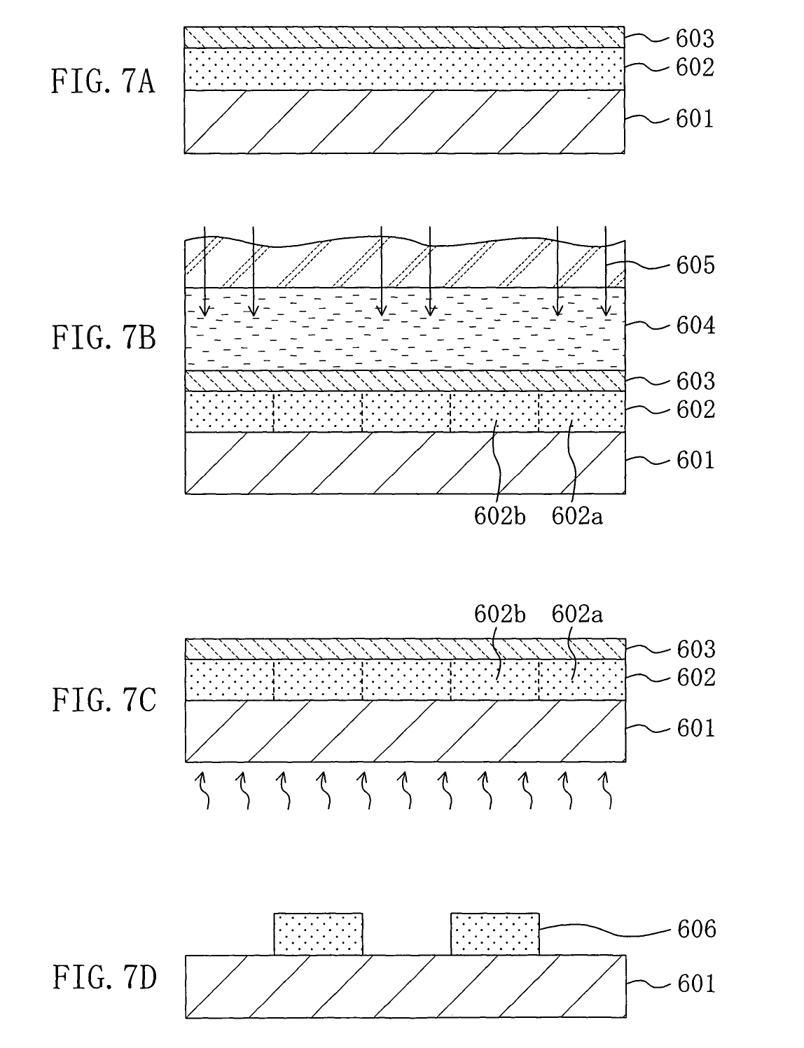

A pattern formation method according to Embodiment 6 of the invention will now be described with reference to FIGS. 7A through 7D.

First, a positive chemically amplified resist material having the following composition is prepared:

| | |
|---|---|
| Base polymer: poly((norbornene-5-methylene-t- | 2 g |
| butylcarboxylate) - (maleic | |
| anhydride)) (wherein norbornene-5-methylene-t- | |
| butylcarboxylate:maleic anhydride = 50 mol %: | |
| 50 mol %) | |
| Acid generator: triphenylsulfonium nonaflate | 0.045 g |
| Solvent: propylene glycol monomethyl ether acetate | 20 g |

Next, as shown in FIG. 7A, the aforementioned chemically amplified resist material is applied on a substrate 601 so as to form a resist film 602 with a thickness of 0.20 μm. Thereafter, a water-soluble film 603 of a polyvinyl pyrrolidone film including 4 wt % of N-(trifluoromethylsulfonyloxy)succinimide, that is, an acid generator for generating an acid through irradiation with light, and 5 wt % of benzopinacol, that is, a compound for generating water in the presence of an acid, is formed on the resist film 602.

Then, as shown in FIG. 7B, while supplying, onto the water-soluble film 603, a solution 604 of perfluoropolyether that is circulated and temporarily stored in the solution storage 14 (shown in FIG. 1), pattern exposure is carried out by irradiating the water-soluble film 603 and the resist film 602 with exposing light 605 of F₂ laser with NA of 0.60 through a mask not shown. Thus, an exposed portion 602a of the resist film 602 becomes soluble in an alkaline developer because an acid is generated from the acid generator therein while an unexposed portion 602b of the resist film 602 remains insoluble in an alkaline developer because no acid is generated from the acid generator therein. Also, in an exposed portion of the water-soluble film 603, water is generated from the compound because an acid is generated from the acid generator.

After the pattern exposure, as shown in FIG. 7C, the resist film 602 is baked with a hot plate at a temperature of 100° C. for 60 seconds, and the resultant resist film is developed with a 2.38 wt % tetramethylammonium hydroxide developer (alkaline developer). In this manner, the water-soluble film 603 and the exposed portion 602a of the resist film 602 are dissolved in the alkaline developer, and hence, a resist pattern 605 made of the unexposed portion 602b of the resist film 602 and having a line width of 0.06 μm can be formed in a good shape as shown in FIG. 7D.

In Embodiment 6, since the water-soluble film 603 includes the acid generator and the compound for generating water in the presence of an acid, the surfaces of the water-soluble film 603 and the resist film 602 can attain affinity owing to generated water after the pattern exposure, so that the developer can easily permeate into the exposed portion 602a of the resist film 602. As a result, the resist pattern 605 can be formed in a good shape.

Although the water-soluble film 603 includes 4 wt % of the acid generator and 5 wt % of the compound for generating water in the presence of an acid in Embodiment 6, the amounts of the acid generator and the compound included in the water-soluble film 603 are not particularly specified but are generally several wt %, respectively.

Also, although the positive chemically amplified resist material is used in Embodiment 6, a positive non-chemically amplified resist material may be used instead.

### EMBODIMENT 7

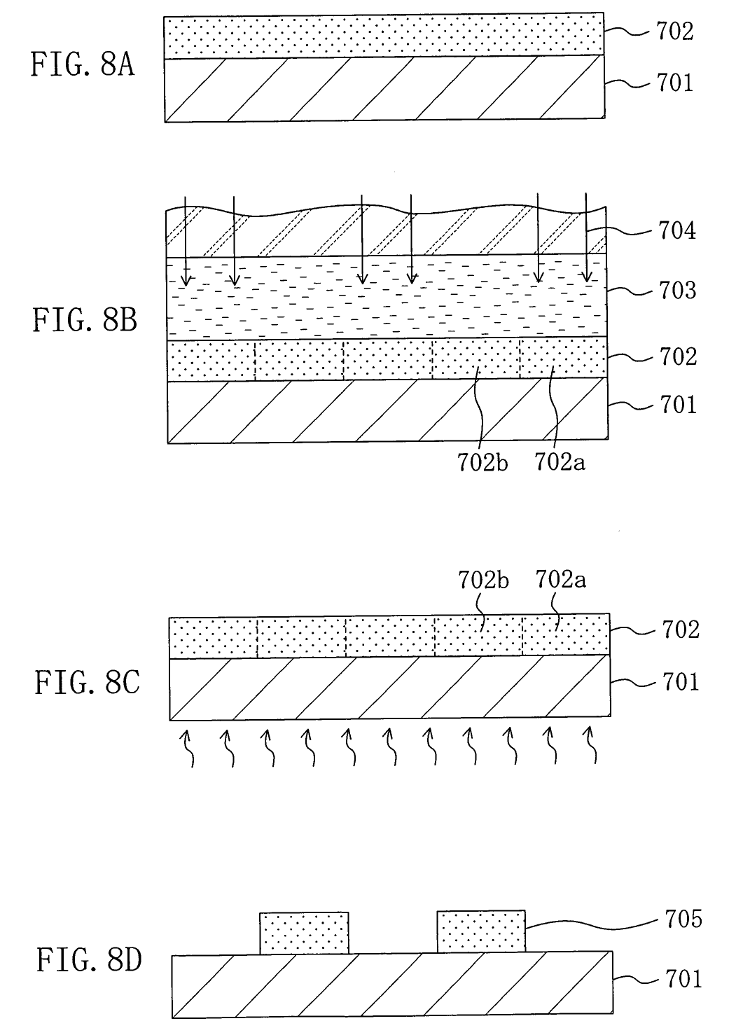

A pattern formation method according to Embodiment 7 of the invention will now be described with reference to FIGS. 8A through 8D.

First, a positive chemically amplified resist material having the following composition is prepared:

| | |
|---|---|
| Base polymer: poly((norbornene-5-methylene-t- | 2 g |
| butylcarboxylate) - (maleic | |
| anhydride)) (wherein norbornene-5-methylene-t- | |
| butylcarboxylate:maleic anhydride = 50 mol %: | |
| 50 mol %) | |
| Acid generator: triphenylsulfonium nonaflate | 0.06 g |
| Compound for generating water in the presence of acid: | 0.12 g |
| 3-methyl-1,2-butanediol | |
| Solvent: propylene glycol monomethyl ether acetate | 20 g |

Next, as shown in FIG. 8A, the aforementioned chemically amplified resist material is applied on a substrate 701 so as to form a resist film 702 with a thickness of 0.20 μm.

Then, as shown in FIG. 8B, while supplying, onto the resist film 702, a nonaqueous solution 703 of perfluoropolyether (having a refractive index n of 1.37) that is circulated and temporarily stored in the solution storage 14 (shown in FIG. 1), pattern exposure is carried out by irradiating the resist film 702 with exposing light 704 of F₂ laser with NA of 0.60 through a mask not shown. Thus, an exposed portion 702a of the resist film 702 becomes soluble in an alkaline developer and water is generated in the exposed portion 702a because an acid is generated from the acid generator therein. On the other hand, an unexposed portion 702b of the resist film 702 remains insoluble in an alkaline developer and no water is generated in the unexposed portion 702b because no acid is generated from the acid generator therein.

After the pattern exposure, as shown in FIG. 8C, the resist film 702 is baked with a hot plate at a temperature of 100° C. for 60 seconds, and the resultant resist film is developed with a 2.38 wt % tetramethylammonium hydroxide developer (alkaline developer). In this manner, a resist pattern 705 made of the unexposed portion 702b of the resist film 702 and having a line width of 0.06 tm can be formed in a good shape as shown in FIG. 8D.

In Embodiment 7, since the resist film 702 includes the acid generator and the compound for generating water in the presence of an acid, the surface of the exposed portion 702a of the resist film 702 can attain affinity owing to generated water after the pattern exposure, so that the developer can easily permeate into the exposed portion 702a of the resist film 702. As a result, the resist pattern 705 can be formed in a good shape.

The amount of the compound for generating water in the presence of an acid included in the chemically amplified resist material in Embodiment 7 is not particularly specified but is generally several wt %.

Although F₂ laser is used as the exposing light in each of Embodiments 1 through 7, another vacuum UV, UV such as a g-line or an i-line, or deep UV such as KrF laser, ArF laser, Kr₂ laser, ArKr laser or Ar₂ laser can be used instead.

In each of Embodiments 3 through 7, the solution may include water. Thus, the affinity of the surface of the resist film can be improved, so as to further accelerate the permeation of the developer into the resist film.

In each of Embodiments 5 through 7, the solution may include a compound for generating water in the presence of an acid. Thus, the affinity of water generated by the acid generated in the exposed portion of the resist film can further accelerate the permeation of the developer into the resist film.

In Embodiment 3 or 5, the chemically amplified resist material can additionally include a compound for generating water in the presence of an acid. Thus, the affinity of water generated owing to the acid generated in the exposed portion of the resist film can further accelerate the permeation of the developer into the resist film.

In each of Embodiments 1 through 7, as the acid generator included in the chemically amplified resist material, the solution or the water-soluble film, any of an onium salt, a halogen-containing compound, a diazoketone compound, a diazomethane compound, a sulfone compound, a sulfonic ester compound and a sulfonimide compound can be used.

Examples of the onium salt usable as the acid generator are diphenyliodonium triflate, triphenylsulfonium triflate and triphenylsulfonium nonaflate.

Examples of the halogen-containing compound usable as the acid generator are 2-phenyl-4,6-bis(trichloromethyl)-s-triazine and 2-naphthyl-4,6-bis(trichloromethyl)-s-triazine.

Examples of the diazoketone compound usable as the acid generator are 1,3-diphenyldiketo-2-diazopropane, 1,3-dicyclohexyldiketo-2-diazopropane and an ester of 1,2-naphthoquinonediazido-4-sulfonic acid and 2,2,3,4,4′-tetrahydroxybenzophenone.

Examples of the diazomethane compound usable as the acid generator are bis(trifluoromethylsulfonyl)diazomethane, bis(cyclohexylsulfonyl)diazomethane, bis(phenylsulfonyl)diazomethane, bis(p-tolylsulfonyl)diazomethane and bis(p-chlorophenylsulfonyl)diazomethane.

Examples of the sulfone compound usable as the acid generator are 4-trisphenacylsulfone, mesitylphenacylsulfone and bis(phenylsulfonyl)methane.

Examples of the sulfonic ester compound usable as the acid generator are benzoin tosylate, 2,6-dinitrobenzyl tosylate, 2-nitrobenzyl tosylate, 4-nitrobenzyl tosylate and pyrogallol trimesylate.

Examples of the sulfonimide compound usable as the acid generator are N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hepto-5-en-2,3 -dicarboxylimide, N-(trifluoromethylsulfonyloxy)-7-oxabicyclo[2.2.1]hepto-5-en-2,3-dicarboxylimide, N-(trifluoromethylsulfonyloxy)bicyclo[2.2.1]heptane-5,6-oxy-2,3-dicarboxylmide, N-(trifluoromethylsulfonyloxy)naphthyldicarboxylimide, N-(camphorsulfonyloxy)succinimide, N-(camphorsulfonyloxy)phthalimide, N-(camphorsulfonyloxy)diphenylmaleimide, N-(camphorsulfonyloxy)bicyclo[2.2.1]hepto-5-en-2,3-dicarboxylimide, N-(camphorsulfonyloxy)-7-oxabicyclo[2.2.1]hepto-5-en-2,3-dicarboxylimide, N-(camphorsulfonyloxy)bicyclo[2.2.1]heptane-5,6-oxy-2,3-dicarboxylimide, N-(camphorsulfonyloxy)naphthyldicarboxylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hepto-5-en-2,3-dicarboxylimide, N-(4-methylphenylsulfonyloxy)-7-oxabicyclo[2.2.1]hepto-5-en-2,3-dicarboxylimide, N-(4-methylphenylsulfonyloxy)bicyclo[2.2.1]heptane-5,6-oxy-2,3-dicarboxylimide and N-(4-methylphenylsulfonyloxy)naphthyldicarboxylimide.

In each of Embodiments 3 through 7, as the compound for generating water in the presence of an acid included in the chemically amplified resist material, the solution or the water-soluble film, a tertiary alcohol, a diol of a tertiary alcohol, a secondary alcohol or a diol of a secondary alcohol can be used.

Examples of the tertiary alcohol usable as the compound for generating water in the presence of an acid are tertiary butanol and 2-methyl-2-butanol.

Examples of the diol of a tertiary alcohol usable as the compound for generating water in the presence of an acid are 3-methyl-1,3-butanediol and benzopinacol.

Examples of the secondary alcohol usable as the compound for generating water in the presence of an acid are 2-propanol, 2-butanol and 2-methyl-3-butanol.

Examples of the diol of a secondary alcohol usable as the compound for generating water in the presence of an acid are 3-methyl-1,2-butanediol and 2,4-pentanediol.

In Embodiment 5 or 6, a polyvinyl alcohol film, a polyvinyl pyrrolidone film or the like can be appropriately used as the water-soluble film.

1. A pattern formation method comprising the steps of:
forming a resist film;
performing pattern exposure by selectively irradiating said resist film with exposing light while supplying, onto said resist film, an immersion solution including a material having an affinity with a developer; and
forming a resist pattern by developing said resist film after the pattern exposure.

2. A pattern formation method comprising the steps of:
forming resist film;
performing pattern exposure by selectively irradiating said resist film with exposing light while supplying, onto said resist film, a nonaqueous solution including water; and
forming a resist pattern by developing said resist film after the pattern exposure.

3. A pattern formation method comprising the steps of:
forming a chemically amplified resist material including an acid generator for generating an acid through irradiation with light;
performing pattern exposure by selectively irradiating said resist film with exposing light while supplying onto said resist film, an immersion solution including a compound for generating a material having an affinity with a developer in the presence of an acid; and
forming a resist pattern by developing said resist film after the pattern exposure.

4. A pattern formation method of claim 3,
wherein said chemically amplified resist material includes a compound for generating a material having an affinity with a developer in the presence of an acid.

5. A pattern formation method comprising the steps of:
forming a resist film;
performing pattern exposure by selectively irradiating said resist film with exposing light while supplying, onto said resist film, an immersion solution including an acid generator for generating an acid through irradiation with light and a compound for generating a material having an affinity with a developer in the presence of an acid; and
forming a resist pattern by developing said resist film after the pattern exposure.

6. A pattern formation method comprising the steps of:
forming a chemically amplified resist material including an acid generator for generating an acid through irradiation with light;
forming, on said resist film, a water-soluble film including a compound for generating a material having an affinity with a developer in the presence of an acid;
performing pattern exposure by selectively irradiating said resist film with exposing light while supplying an immersion solution onto said water-soluble film; and
forming a resist pattern by developing said resist film after the pattern exposure.

7. The pattern formation method of claim 6,
wherein said immersion solution includes a compound for generating a material having an affinity with a developer in the presence of an acid.

8. The pattern formation method of claim 6, wherein said chemically amplified resist material includes a compound for generating a material having an affinity with a developer in the presence of acid.

9. A pattern formation method comprising the steps of:
forming a resist film;
forming, on said resist film a water-soluble film including an acid generator for generating an acid through irradiation with light and a compound for generating a material having an affinity with a developer in the presence of an acid;
performing pattern exposure by selectively irradiating said resist film with exposing light while supplying an immersion solution onto said water-soluble film; and
forming a resist pattern by developing said resist film after the pattern exposure.

10. The pattern formation method of claim 9, wherein said immersion solution includes a compound for generating a material having an affinity with a developer in the presence of acid.

11. A pattern formation method comprising the steps of:
forming a chemically amplified resist material including an acid generator for generating an acid through irradiation with light and a compound for generating a material having an affinity with a developer in the presence of an acid,
performing pattern exposure by selectively irradiating said resist film with exposing light while supplying an immersion solution onto said resist film; and
forming a resist pattern by developing said resist film after the pattern exposure.

12. The pattern formation method of claim 11, wherein said immersion solution includes a compound for generating a material having an affinity with a developer in the presence of an acid.

13. The pattern formation method of any of claims 1, 2, 3, 5, 6, 9 and 11,
wherein said exposing light is KrF excimer laser, ArF excimer laser, F₂ laser, KrAr laser, or Ar₂ laser.

14. The pattern formation method of any of claims 1, 2, 3, 5, 6, 9 and 11,
wherein a material having an affinity with a developer is added to said nonaqueous solution.

15. The pattern formation method of any of claims 3, 5, 6, 9 and 11,
wherein said acid generator is an onium salt, a halogen-containing compound, a diazoketone compound, a diazomethane compound, a sulfone compound, a sulfonic ester compound or a sulfonimide compound.

16. The pattern formation method of any of claims 3, 5, 6, 9, and 11,
wherein said acid generator is an onium salt selected from the group consisting of diphenyliodonium triflate, triphenylsulfonium triflate and triphenylsulfonium nonaflate.

17. The pattern formation method of any of claims 3, 5, 6, 9 and 11,
wherein said acid generator is a halogen-containing compound selected from the group consisting of 2-phenyl-4,6-bis(trichloromethyl)-s-triazine and 2-naphthyl-4,6-bis(trichloromethyl)-s-triazine.

18. The pattern formation method of any of claims 3, 5, 6, 9 and 11,
wherein said acid generator is a diazoketone compound selected from the group consisting of 1,3-diphenyldiketo-2-diazopropane, 1,3-dicyclohexyldiketo-2-diazopropane and an ester of 1,2-naphthoquinonediazido-4-sulfonic acid and 2,2,3,4,4′-tetrahydroxybenzophenone.

19. The pattern formation method of any of claims 3, 5, 6, 9 and 11,
wherein said acid generator is a diazomethane compound selected from the group consisting of bis(trifluoromethylsulfonyl)diazomethane, bis(cyclohexylsulfonyl)diazomethane, bis(phenylsulfonyl)diazomethane, bis(p-tolylsulfonyl)diazomethane and bis(p-chlorophenylsulfonyl)diazomethane.

20. The pattern formation method of any of claims 3, 5, 6, 9 and 11,
wherein said acid generator is a sulfone compound selected from the group consisting of 4-trisphenacylsulfone, mesitylphenacylsulfone and bis(phenylsulfonyl)methane.

21. The pattern formation method of any of claims 3, 5, 6, 9 and 11,
wherein said acid generator is a sulfonic ester compound selected from the group consisting of benzoin tosylate, 2,6-dinitrobenzyl tosylate, 2-nitrobenzyl tosylate, 4-nitrobenzyl tosylate and pyrogallol trimesylate.

22. The pattern formation method of any of claims 3, 5, 6, 9 and 11,
wherein said acid generator is a sulfonimide compound selected from the group consisting of N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hepto-5-en-2,3-dicarboxylimide, N-(trifluoromethylsulfonyloxy)-7-oxabicyclo[2.2.1]hepto-5-en-2,3-dicarboxylimide, N-(trifluoromethylsulfonyloxy)bicyclo[2.2.1]heptane-5,6-oxy-2,3-dicarboxylmide, N-(trifluoromethylsulfonyloxy)naphthyldicarboxylimide, N-(camphorsulfonyloxy)succinimide, N-(camphorsulfonyloxy)phthalimide, N-(camphorsulfonyloxy)diphenylmaleimide, N-(camphorsulfonyloxy)bicyclo[2.2.1]hepto-5-en-2,3-dicarboxylimide, N-(camphorsulfonyloxy)-7-oxabicyclo[2.2.1]hepto-5-en-2,3dicarboxylimide, N-(camphorsulfonyloxy)bicyclo[2.2.1]heptane-5,6-oxy-2,3dicarboxylimide, N-(camphorsulfonyloxy)naphthyldicarboxylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hepto-5-en-2,3-dicarboxylimide, N-(4-methylphenylsulfonyloxy)-7-oxabicyclo[2.2.1]hepto-5-en-2,3-dicarboxylimide, N-(4-methylphenylsulfonyloxy)bicyclo[2.2.1]heptane-5,6-oxy-2,3-dicarboxylimide and N-(4-methylphenylsulfonyloxy)naphthyldicarboxylimide.

23. The pattern formation method of any of claims 1, 2, 3, 5, 6, 9 and 11,
wherein said material having an affinity with a developer is a tertiary alcohol, a diol of a tertiary alcohol, a secondary alcohol or a diol of a secondary alcohol.

24. The pattern formation method of any of claims 1, 2, 3, 5, 6, 9 and 11,
wherein said material having an affinity with a developer is a tertiary alcohol selected from the group consisting of t-butanol and 2-methyl-2-butanol.

25. The pattern formation method of any of claims 1, 2, 3, 5, 6, 9 and 11,
wherein said material having an affinity with a developer is a diol of a tertiary alcohol selected from the group consisting of 3-methyl-1,3,-butandiol and benzopinacol.

26. The pattern formation method of any of claims 1, 2, 3, 5, 6, 9 and 11,
wherein said material having an affinity with a developer is a secondary alcohol selected from the group consisting of 2-propanol, 2-butanol and 2-methyl-3-butanol.

27. The pattern formation method of any of claims 1, 2, 3, 5, 6, 9 and 11,
wherein said material having an affinity with a developer is a diol of a secondary alcohol selected from the group consisting of 3-methyl-1,2-butandiol and 2,4-pentanediol.

28. The pattern formation method of claim 6 or 9,
wherein said water-soluble film is a polyvinyl alcohol film or a polyvinyl pyrrolidone film.

29. The pattern formation method of any of claims 1, 2, 3, 5, 6, 9 and 11, wherein said immersion solution is perfluoropolyether or water.
